(19) United States
(12) Patent Application Publication
(10) Pub. No.: US 2026/0140160 A1
(43) Pub. Date: May 21, 2026

(54) COMMISSIONING OF A TEST ARRANGEMENT

(71) Applicant: OMICRON ELECTRONICS GMBH, Klaus (AT)

(72) Inventors: Florian REIN, Feldkirch (AT); Thomas BLOCHER, Feldkirch (AT)

(73) Assignee: OMICRON ELECTRONICS GMBH, Klaus (AT)

(21) Appl. No.: 19/113,682

(22) PCT Filed: Sep. 19, 2023
(86) PCT No.: PCT/EP2023/075741

§ 371 Date: Mar. 20, 2025

(30) Foreign Application Priority Data
Sep. 21, 2022 (AT) A50727/2022

(51) Int. Cl. G01R 31/01; G01R 35/00

(52) U.S. Cl. CPC G01R 31/01; G01R 35/00

(57) ABSTRACT

Test arrangement, which includes test components interconnected via a data bus safer, and method of operating the test arrangement. Test components of the test devices are connected according to a specified test configuration; at least one test device having a functional-test unit is defined as an initiator device; all test components connected to the data bus are determined and stored as a test-component list in the initiator device; the test-component list is transmitted to a verification unit connected to the initiator device and displayed; the displayed test-component list is checked; the displayed test-component list is confirmed when it corresponds to the specified test configuration, and the test-component list is transmitted as a user configuration list to the initiator device and compared with the test-component list; and the test arrangement is brought into a ready-for-operation state when the user configuration list received corresponds to the stored test-component list.

The present invention relates to a method for commissioning a test arrangement comprising a plurality of test devices each having at least one test component, wherein the test components of the test devices are connected to one another via a data bus in order to perform a test task. The invention also relates to a corresponding arrangement.

A test device can be used to carry out measurements on electrical test objects such as current transformers, voltage transformers, protective devices and protective relays, transformers, electrical switch cabinets, electrical distribution boards, etc. The electrical test objects are in particular parts of electrical power generation, power transmission or power distribution systems. To carry out a measurement, the test device must be electrically connected to the test object. Performing measurements on such test objects is potentially dangerous, as a test object can store or carry a dangerous amount of electrical energy. Therefore, sufficient safety precautions must be taken when carrying out measurements in order to protect the test device and the test objects, but above all the test personnel. For this reason, the test device can be extended to a test arrangement by adding further test components. For example, a work area that is dangerous for test personnel can be equipped with warning lights and emergency stop switches as test components. Emergency stop switches can enable a current and/or voltage amplifier in the test device to be switched off quickly and safely. Warning lamps, on the other hand, can indicate whether the test object or work area is safe (de-energized or discharged) or unsafe (energized). As a further test component, a switch-on protection can be provided to prevent the tester from being switched on without authorization. Activating a switch-on protection can be an important safety aspect, especially when a person is working on the wiring. A test arrangement can also comprise several test devices that can be connected to one another, for example via a data bus. A test arrangement thus comprises test devices and a plurality of test components, such as warning lamps, emergency stop switches, switch-on protections, etc. The test arrangement is formed by connecting the test components to one another via a data bus, which allows the test components to communicate with one another via data communication over the data bus, for example to perform a specified test task. With such a test arrangement consisting of test components connected and communicating with one another via a data bus, it is important, also for safety reasons, to provide a functional test of the test arrangement.

WO 2021/074373 A1 describes such a test arrangement with a functional test. The components are connected to one another in a ring bus. A bus master transmits a data package cyclically, which is forwarded by each bus subscriber (component). When the data package arrives back at the bus master, a closed, and therefore intact, ring bus can be assumed, Each bus subscriber has a standby status that is set to active or inactive depending on a cyclical function test in the bus subscriber. The bus master sends a ready signal to the next component when the ring bus is closed. If the ready status is active in this component, this component sends the ready signal further to the next component in the ring bus and so on. If the bus master receives the ready signal back, it is assumed that the test arrangement is ready for operation. The desired test can then be embodied on the test object with the test arrangement ready for operation.

This functional test requires a wired ring bus in which all components required for testing the test object and safely performing the test are present and integrated into the ring bus. However, errors can also occur during wiring, especially with larger test arrangements with many components, so that it can happen that a test is started or carried out with a test arrangement that does not correspond to the desired or even the prescribed configuration. For example, an emergency stop switch or a signal lamp or warning light may have been forgotten when wiring. This can lead to dangerous situations during the test, especially for the test personnel. Damage to components, in particular a test device, is also possible.

It is thus an object of the present invention to make the execution of a test with a test arrangement comprising a plurality of test components which are interconnected via a data bus safer.

This object is achieved by the features of the independent claims. According to the invention, before the test is carried out, a commissioning is performed to determine whether the actual test arrangement corresponds to that specified by the test task. Only then does the test arrangement switch to a ready-for-operation state in which the test can be carried out. Otherwise, the test arrangement remains in a non-ready-for-operation state in which no test can be started with the test arrangement. This can increase safety when carrying out a test with a test arrangement.

The test arrangement can easily be transferred to a ready-for-operation state by transferring the initiator device to a ready-for-operation state. This means that the test device used to carry out the functional test controls itself when the test arrangement switches to the ready-for-operation state.

The ready-for-operation state can preferably be displayed to the user if a display unit is activated by the initiator device when the test arrangement enters a ready-for-operation state. For this purpose, a display unit on the initiator device can be activated or a test component of a test device designed as a display unit can be activated by the initiator device.

If the check is repeated at predetermined time intervals by the initiator device redetermining the test component list at predetermined time intervals and carrying out the comparison of the stored user configuration list with each newly determined test component list and the test arrangement remains in the ready-for-operation state if the stored user configuration list corresponds to the new test component list and otherwise changes to a non-ready-for-operation state, the security of the test arrangement can also be improved during operation of the test arrangement. The user configuration list is the last test component list saved and confirmed by the user. If an error occurs during the test task being carried out with the test arrangement that leads to an incorrect configuration of the test arrangement, this can be detected and the test arrangement can be transferred to a non-ready-for-operation state.

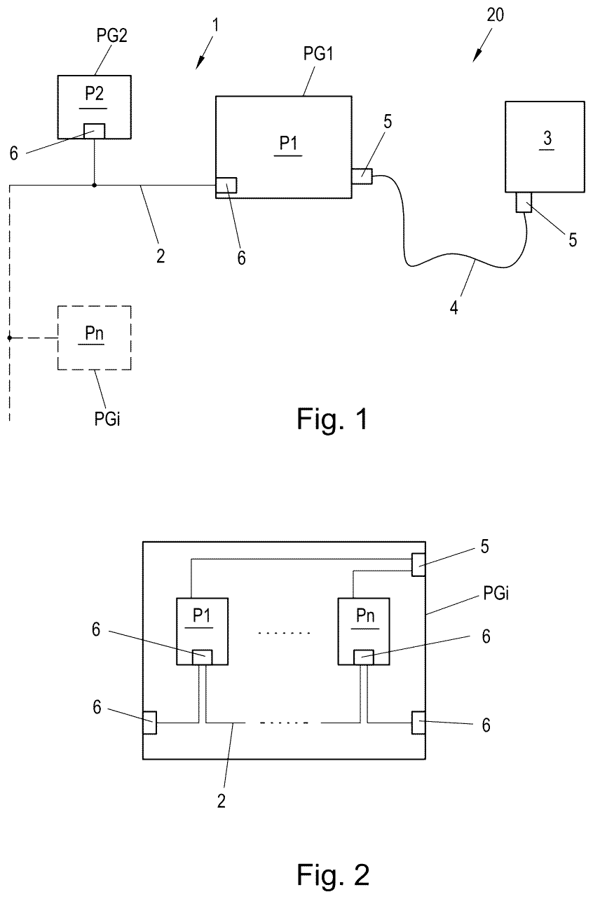

The present invention will be described in greater detail below with reference to FIG. 1 to 5, which by way of example show schematic and non-limiting advantageous embodiments of the invention. In the figures:

FIG. 1 is the use of a test arrangement for carrying out a test task on a test object,

FIG. 2 is a test device with several test components,

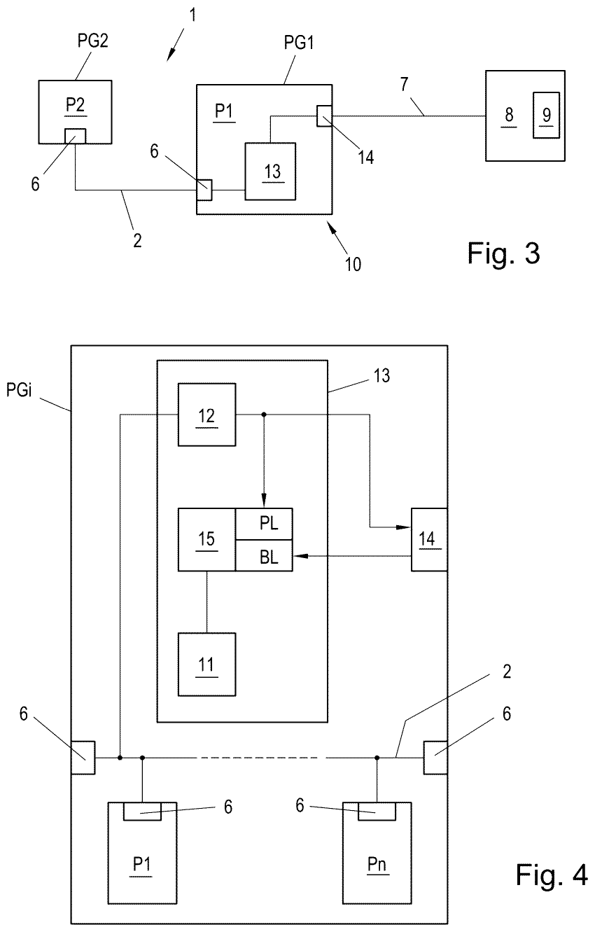

FIG. 3 is an arrangement for carrying out the functional check of a test arrangement,

FIG. 4 is a test device with a function check unit and

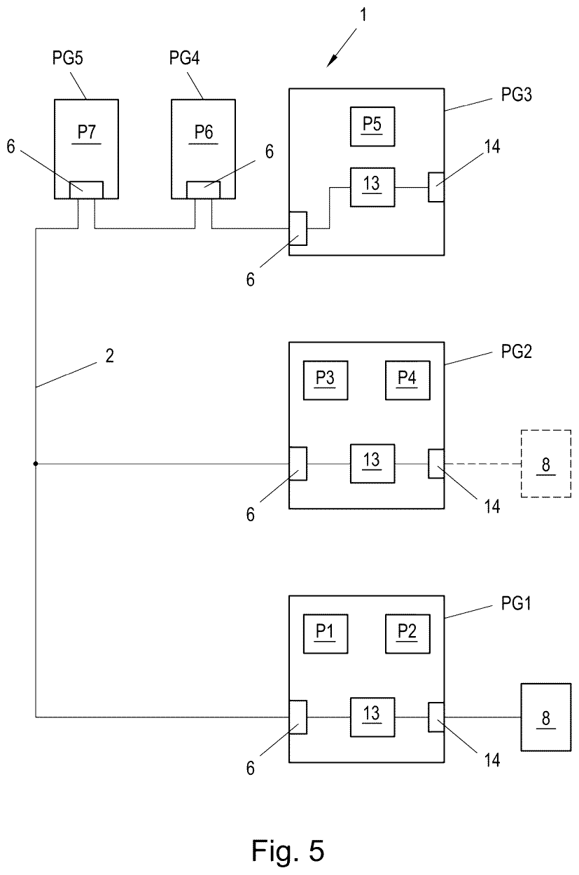

FIG. 5 is a test arrangement with several test devices with function check unit.

FIG. 1 shows a configuration of a test arrangement 1 consisting of two test devices PGi, each with at least one test component Pn. i and n serve as an index to differentiate between the various test devices PGi and test components Pn. If the respective part is addressed in general, “PGi” or “Pn” is used, otherwise the test devices and test components are differentiated by the respective index. In general, n≥i applies.

The test arrangement 1 comprises a plurality i>1 of test devices PGi, wherein each test device PGi comprises at least one test component Pn. The test components Pn are connected to one another via a data bus 2, for example wired together via a data cable. The data bus 2 ensures that every test component Pn can communicate with every other test component Pn via the data bus 2 by means of data transmission via the data bus 2.

The data bus 2 can be wired or wirelessly embodied. A hybrid form with a partially wireless and partially wired data bus 2 is also conceivable. Preferably, the entire data bus 2 of the test arrangement 1 is wired. In the case of an at least partially wired data bus 2, at least two test components Pn are wired together via a data cable, forming the data bus 2 between these test components Pn. In the case of an at least partially wireless data bus 2, at least two test components Pn are coupled to one another via a wireless data communication link, for example radio, WLAN, Bluetooth, etc.

The bus topology of the data bus 2 resulting from the connection of the test components Pn is irrelevant for the invention. The data bus 2 can be in the form of a ring bus, line bus, star bus, mesh bus, tree bus, etc., for example. The data communication protocol implemented for data transmission is also irrelevant to the invention. It is also irrelevant whether bidirectional or unidirectional data transmission is possible via data bus 2.

A test component Pn thus has at least one data bus data interface 6 to the data bus 2, via which the test component Pn can be connected to at least one other test component Pn via the data bus 2. The data bus data interface 6 enables data transmission of the test component Pn via the connected data bus 2.

A test component Pn can be, for example, a warning lamp, signal lamp, acoustic signal transmitter, emergency stop switch, switch-on protection, etc., but also a current amplifier for generating an electrical current at a current output or a voltage amplifier for generating an electrical voltage at a voltage output.

It is also conceivable that several test components Pn are integrated in one test device PGi, as represented in FIG. 2. For example, several current amplifiers and/or voltage amplifiers can be installed in a test device PGi as test components Pn, possibly also with further test components Pn, such as emergency stop switches or signal lamps. If several test components Pn are integrated in a test device PGi, these test components Pn are already connected to one another in the test device PGi via a data bus 2, preferably wired, as shown in FIG. 2, for example. Such a test device PGi can also be connected to a further test device PGi, each with at least one test component Pn, to form a test arrangement 1. For this purpose, the test device PGi has at least one data bus data interface 6, with which the test device PGi, specifically the test components Pn connected to one another in the test device PGi via a data bus 2, can be connected to another test device PGi via the data bus 2.

To carry out a test task with the test arrangement 1, at least one test component Pn of the test arrangement 1 is electrically connected to a test object 3, for example by means of a test cable 4, as in the embodiment shown in FIG. 1. Suitable contacts 5, such as a plug connection, can also be provided on the test cable 4, as well as on the test object 3 and/or on the test component Pn. In a configuration of a test device PGi with several test components Pn, it is also possible to connect several test components Pn to a test object 3 via a common test cable 4. A multi-pole contact 5 and a multi-pole test cable 4 can be provided for this purpose, as indicated in FIG. 2.

However, the test object 3, and possibly a test cable 4, are not part of the test arrangement 1, but form a test arrangement 20 with a test arrangement 1 and a test object 3, which are electrically connected to one another.

Any electrical device can be used as test object 3. A test object 3 is, for example, an electrical component of a system for the generation, transmission or distribution of electrical energy, e.g. an electrical supply network. Such components are, for example, safety devices, such as protective devices, protective relays, reclosing devices, circuit breakers or disconnecting switches, or measuring apparatus, such as current transformers or voltage transformers, or electrical voltage transformers, such as transformers, power converters, etc., devices for generating electrical energy, such as generators, etc., or an electrical distributor with securing elements and/or switching elements. This list is only exemplary and not exhaustive. How and with what the test object 3 and a test component Pn are electrically connected depends of course on the test object 3 but also on the type of test task.

For safety reasons, the test arrangement 1 must be subjected to a functional test before commissioning, i.e. before carrying out a test task. The test arrangement 1 should only be transferred to a ready-for-operation state when the functional test has been successfully completed. Otherwise, the test arrangement 1 should remain in a non-operational state in which the test arrangement 1 cannot be put into operation. The invention relates to a method for commissioning the test arrangement 1, by which an aspect of the functionality of the test arrangement 1 is tested and which is explained with reference to FIGS. 3 and 4. In addition, further functional tests can also be carried out on the test arrangement 1, for example as described in WO 2021/074373 A1 .

The first step of the method is to connect, for example wiring or setting up the wireless connection, the test components Pn, if necessary. This is done according to a predefined test configuration of the test components Pn involved in the test task, which form the test arrangement 1. The test configuration can be in the form of a configuration list with all test components Pn involved. The connection is made by test personnel who are to carry out the test task with the test arrangement 1.

The test configuration contains at least a list of all test component types involved in the test arrangement 1, for example current amplifiers, voltage amplifiers, warning lights, emergency stop switches, etc.

The connection creates the data bus 2, which connects the test components Pn of the test arrangement 1. The test configuration is specified by the test task to be carried out, and in particular determines which test components Pn must be present in the test arrangement 1 in order to carry out the test task. For example, at least one test device PG1 with at least one test component P1 in the form of a current or voltage amplifier and at least one further test device PG2 with a warning light as test component P2 can be specified, as represented in FIG. 3.

It is also possible that the test configuration not only specifies the test components Pn to be provided, but also a certain sequence for connecting the test devices PGi or test components Pn.

The next step in the method is to define at least one test device PGi with a function check unit 13 as the initiator device 10, in FIG. 3 for example the test device PG1. Further functionalities for carrying out the method according to the invention are implemented in the function check unit 13, as will be explained in detail below. A function check unit 13 does not have to be implemented in every test device PGi, but there must be at least one test device PGi with a function check unit 13 in the test arrangement 1, and thus at least one test device PGi that can act as an initiator device 10.

The function check unit 13 comprises at least a storage unit 15, a comparator unit 11 and a bus detection unit 12. For this purpose, microprocessor-based hardware, such as a microcontroller, can be provided in the test device PGi with the function check unit 13, on which certain functionalities, such as those of the comparator unit 11 and/or the bus detection unit 12, are embodied as software running on the microprocessor-based hardware. The storage unit 15 can be a storage component or a storage of the microprocessor-based hardware. The function check unit 13, or certain functionalities thereof, can also be implemented on a stand-alone control unit of a test device PGi, for example as software. For example, a control unit of a PGi test device runs firmware of the PGi test device, which is used to carry out functions of the PGi test device.

To carry out the functional test, the initiator device 10 is connected to a verification unit 8. For this purpose, a suitable data interface 14 is provided on the initiator device 10, via which the verification unit 8 is connected to the initiator device 10 via a data connection 7. The data interface 14 is, for example, a USB port or a wireless interface such as Bluetooth or WLAN.

The verification unit 8 interacts with the function check unit 13 connected to it in the initiator device 10 to carry out the function check.

The verification unit 8 is preferably a microprocessor-based hardware, for example a microcontroller, a computer, a mobile apparatus or a mobile terminal, on which corresponding software for carrying out the function check runs in interaction with the function check unit 13.

As the next step of the method according to the invention, the initiator device 10, specifically the bus detection unit 12 of the function check unit 13 of the initiator device 10, determines all test components Pn connected to the data bus 2. The bus detection unit 12 is connected to the data bus 2 for this purpose.

All PGi test devices connected to data bus 2 can be determined in a variety of ways. For example, the initiator device 10 can send a bus message to all test components Pn via the data bus 2, with the request to transmit a presence message. The test components Pn then each transmit a presence message to the initiator device 10, so that all test components Pn can be detected. It would also be conceivable that all test components Pn send presence messages at regular intervals via the data bus 2, which are read by the initiator device 10. In addition, there are of course further possibilities for determining all test components Pn present on data bus 2.

At least the test component type is transmitted in a presence message, i.e. information on what type of device it is, for example a current amplifier, voltage amplifier, warning light, signal light, emergency stop switch, etc. In addition, a unique identification of the respective test component Pn, a position in the data bus 2, a SW or HW version number or other information can also be transmitted.

All test components Pn connected to the data bus 2 are stored in a test component list PL in the initiator device 10, specifically in the storage unit 15 of the function check unit 13.

The test component list PL comprises at least a list of the test component types of all test components Pn that can be reached on the data bus 2. It is therefore possible that there are several entries of a certain test component type in the test component list PL.

In the next process step, the determined test component list PL is sent to the verification unit 8 connected to the initiator device 10 via the data interface 14.

The next step in the process is to display the test component list PL transmitted to the verification unit 8 on the verification unit 8 for a user. The format in which the test component list PL is displayed is irrelevant as long as the existing test component types can be determined by the user.

For this purpose, a user interface 9 can be provided on the verification unit 8, for example a visual and/or acoustic display.

This allows the user to check the test component list PL displayed on the verification unit 8, in particular to compare the test component list PL received from the initiator device 10 with the specified test configuration.

If the test component list PL received corresponds to the specified test configuration, the user confirms the test component list PL, for example via an input apparatus of the user interface 9. The verification unit 8 then sends the confirmed test component list PL to the initiator device 10 as a user configuration list BL.

In the initiator device 10, the stored test component list PL is compared with the user configuration list BL received from the verification unit 8. This takes place in the comparator unit 11 of the function check unit 13, which is also connected to the storage unit 15 for this purpose. The comparison thus comprises at least the determination of whether the test component types and the number of test component types in the test component list PL and the user configuration list BL match.

If compliance is established, the test arrangement 1 is transferred to a ready-for-operation state. This can be done by switching the initiator device 10 to a ready-for-operation state. In the ready-for-operation state of the test arrangement 1, the intended test task can be embodied with the test arrangement 1.

If the stored test component list PL does not match the user configuration list BL received from the verification unit 8, then the test arrangement 1, or the initiator device 10, remains in a non-ready-for-operation state and the test arrangement 1 cannot be put into operation.

In order to indicate the ready-for-operation state to the user, this can be displayed by the initiator device 10 on a display unit. The display unit can be part of the initiator device 10, for example a signal lamp on the initiator device 10 or an acoustic signal output. However, it is also possible to provide a test component Pn as a display unit. The test component Pn can be embodied as a signal lamp or acoustic output unit, for example. In this case, the initiator device 10 can send a data message to the test component Pn via the data bus 2 in order to cause the test component Pn to activate the display unit.

The user configuration list BL sent from the verification unit 8 to the initiator device 10 may also remain stored in the initiator device 10, for example in the storage unit 15. This makes it possible to repeat the check of the test arrangement 1 at predetermined intervals. The initiator device 10 repeats the determination of the test component list PL at predefined intervals and checks the test component list PL determined in the process against the stored user configuration list BL. Normally, the test component list PL should not change, so that the test arrangement 1 remains in the ready-for-operation state. However, if there is a deviation between the re-determined test component list PL and the stored user configuration list BL due to an error, such as a cable break in a data cable of the data bus 2 or due to an error in a test component Pn, then the test arrangement 1 is transferred to the non-ready-for-operation state. Any test task that may be running is interrupted.

It may also be provided that several test devices PGi with a function check unit 13 are present in a test arrangement 1, for example as represented in FIG. 5. In this case, the procedure described above can be embodied on several or also on each test device PGi with a function check unit 13, as indicated by a dashed line in FIG. 5. In this embodiment, each test device PGi must therefore be brought into a ready-for-operation state with a function check unit 13 in order to be able to use the test arrangement 1.

The method according to the invention can ensure that a test arrangement 1 only switches to the ready-for-operation state if the actual configuration of the test arrangement 1 (test component list PL) matches the specified test configuration. The user of the test arrangement 1 can determine this easily and safely.

A test device PGi with a function check unit 13 can, for example, be supplied with a user configuration list BL preconfigured at the factory. In order to be able to use such a test device PGi in a specific test arrangement 1, the preconfigured user configuration list BL must first be updated according to the specifications of the test task to be performed with the test arrangement 1 (specified test configuration). The method according to the invention also enables a secure procedure for updating the user configuration list BL.

1. A method for commissioning a test arrangement that includes a plurality of test devices, each of the plurality of test devices having at least one test component, wherein the at least one test components of the plurality of test devices are connected to one another via a data bus for carrying out a test task, the method comprising:
connecting the at least one test components of the plurality of test devices according to a predefined test configuration of the at least one test components involved in the test task;
defining at least one test device of the plurality of test devices having a function check unit as at least one initiator device;
determining all test components connected to the data bus by the function check unit of the at least one initiator device and storage of all test components connected to the data bus in a test component list in the at least one initiator device;
transmitting the test component list to a verification unit connected to the at least one initiator device;
displaying the transmitted test component list on the verification unit;
checking the test component list displayed on the verification unit;
confirming the test component list displayed on the verification unit when the test component list corresponds to the predefined test configuration and transmitting the displayed test component list as a user configuration list from the verification unit to the at least one initiator device;
comparing the user configuration list received from the verification unit and the test component list stored in the initiator device in the at least one initiator device; and
transferring the test arrangement to a ready-for-operation state when the received user configuration list corresponds to the stored test component list.

2. The method according to claim 1, wherein the test arrangement is transferred to a ready-for-operation state by transferring the at least one initiator device to a ready-for-operation state.

3. The method according to claim 1, wherein an indicator unit is activated by the at least one initiator device when the test arrangement enters a ready-for-operation state.

4. The method according to claim 3, wherein a display unit on the at least one initiator device is activated or a test component of a test device designed as a display unit is activated by the at least one initiator device.

5. The method according to claim 1, wherein the user configuration list obtained from the verification unit is stored in the at least one initiator device, wherein the at least one initiator device redetermines the test component list at predetermined intervals and carries out the comparison of the stored user configuration list with each newly determined test component list, and wherein the test arrangement remains in the ready-for-operation state when the stored user configuration list corresponds to the new test component list and otherwise changes to a non-ready-for-operation state.

6. An arrangement for commissioning a test arrangement comprising:
a plurality of test devices, each of the plurality of test devices having at least one test component;
the at least one test component of the plurality of test devices being connected to one another via a data bus for carrying out a test task in accordance with a predetermined test configuration of the at least one test component involved in the test task;
at least one test device of the plurality of test devices, which comprises a function check unit, being defined as an initiator device;
the function check unit comprising a bus detection unit provided in the initiator device, which is set up to determine all test components connected to the data bus, and a storage unit provided in the initiator device, which is set up to store the determined test components in a test component list;
the initiator device being connected to a verification unit to transmit the stored test component list to the connected verification unit and the verification unit being set up to display the transmitted test component list on a user interface, wherein the test component list displayed on the verification unit is checked and the test component list displayed on the verification unit is confirmed at the user interface when the test component list corresponds to the predetermined test configuration;
the verification unit being set up to transmit the displayed test component list to the initiator device as a user configuration list; and
the function check unit further comprising a comparator unit provided in the initiator device, which is set up to compare the user configuration list received from the verification unit and the test component list stored in the initiator device,
wherein the test arrangement changes to a ready-for-operation state when the received user configuration list corresponds to the stored test component list.

7. The arrangement according to claim 6, wherein the test arrangement changes to a ready-for-operation state by the initiator device changing to a ready-for-operation state.

8. The arrangement according to claim 6, wherein the storage unit is set up to store the user configuration list received from the verification unit in the initiator device,
the bus detection unit is set up to redetermine the test component list at predetermined time intervals and the comparator unit is set up to carry out a comparison of the stored user configuration list with each redetermined test component list and
the test arrangement remains in the ready-for-operation state when the stored user configuration list corresponds to a new test component list and otherwise changes to a non-ready-for-operation state.

9. The method according to claim 1, wherein a user checks the test component list displayed on the verification unit and the user confirms the test component list when the test component list displayed on the verification unit corresponds to the predefined test configuration, wherein the displayed test component list is transmitted as a user configuration list from the verification unit to the at least one initiator device.

10. The arrangement according to claim 6, wherein a user checks the test component list displayed on the verification unit and, when the test component list corresponds to the predetermined test configuration, the user confirms the test component list displayed on the verification unit through the user interface.
